(19) United States
(12) Patent Application Publication
(10) Pub. No.: US 2024/0062997 A1
(43) Pub. Date: Feb. 22, 2024

(54) PROCESSING PARTS USING SOLID-STATE ADDITIVE MANUFACTURING

(71) Applicant: Lam Research Corporaton, Fremont, CA (US)

(72) Inventors: Pankaj Jyoti Hazarika, Sherwood, OR (US); Pylin Sarobol, Tigard, OR (US); Matthew Brian Schick, Beaverton, OR (US); Seyedalireza Torbatisarraf, San Jose, CA (US)

(21) Appl. No.: 18/270,481

(22) PCT Filed: Jan. 6, 2022
(86) PCT No.: PCT/US22/11422

§ 371 Date: Jun. 29, 2023

Related U.S. Application Data
(60) Provisional application No. 63/140,140, filed on Jan. 21, 2021.

(51) Int. Cl. H01J 37/32; H01L 21/687; B33Y 80/00; C23C 16/44; C23C 16/458

(52) U.S. Cl. CPC H01J 37/32715; H01J 37/32495; H01L 21/68757; B33Y 80/00; C23C 16/4404; C23C 16/4581; H01J 2237/334; H01J 2237/2007

(57) ABSTRACT

Semiconductor-processing chamber components and methods for making the components are presented. One component includes a base including a metallic material, a metal matrix composite (MMC) layer, and a dielectric layer. The MMC layer at least partially covers the base, and the MMC layer comprises a metallic material as a continuous phase and a non-metallic material as a disperse phase. Further, the MMC layer is formed on the base using solid-state additive manufacturing (SSAM). The dielectric layer is made of a non-metallic material and is directly on the MMC layer.

### CLAIM OF PRIORITY

This application claims the benefit of priority to U.S. Provisional Patent Application Ser. No. 63/140,140, filed on Jan. 21, 2021, which is incorporated by reference herein in its entirety.

### TECHNICAL FIELD

The subject matter disclosed herein generally relates to methods, systems, and machine-readable storage media for manufacturing parts for equipment used in semiconductor manufacturing.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In semiconductor manufacturing equipment, some parts are subject to extreme conditions during operation of the equipment. For example, some parts such as a baseplate that forms part of an Electrostatic Chuck (ESC) in dielectric etch and conductor etch tools for supporting a substrate within a chamber, are subject to extreme conditions, such as high temperatures, rapid changes in temperature, high throughput of electric currents, and so forth.

A baseplate is often composed of at least two layers, such as a base metal layer and a protective dielectric layer above the base metal layer. Often these layers have very different Coefficient of linear Thermal Expansion (CTE) values, and the protective layer on the baseplate can crack and delaminate during usage such as when the part undergoes thermal shock in cryogenic applications with rapid changes in temperature, e.g., 120° C. changes in temperature.

Overtime, the cracking and delamination causes the part to fail.

### SUMMARY

A semiconductor processing chamber includes parts used during plasma-assisted etching or deposition processes. Solid-State Additive Manufacturing (SSAM) is used during fabrication of metal matrix composite (MMC) bulk materials for the chamber parts, also referred to herein as components, including the application of metal, metal alloys, or metal matrix composites. Intermediate layers may be created for the chamber parts to create parts that better resist extreme conditions, such as fast and large changes in temperature, to provide corrosion protection, prevent adhesive failure, and extend chamber part lifetime.

Using SSAM provides several advantages. First, internal channels within the component can be built during the manufacturing process as the part is made layer-by-layer, and SSAM may be used to manufacture the complete component or to add layers, during manufacturing of the component, that include internal channels or internal geometries. Second, the part's thermal conductivity is improved by using layers that have high thermal conductivity, e.g., using SSAM to deposit MMC (e.g., aluminum matrix composites (Al plus Al₂O₃. SiC, Al plus SiC, Al plus a carbon nanotube).

Further, a component can be made out of SSAM MMC or by adding layers using SSAM deposit (e.g., metal deposit, metal alloy deposit, or MMC deposit). In some cases, to enhance the thermal conductivity of the component, an aluminum matrix composite containing a carbon nanotube is used.

In the case where uniform corrosion protection is required for the MMC part (e.g., aluminum part that already contain different phases like Al₂O₃, SiC), SSAM is used to deposit an aluminum layer and then the component is anodized for uniform corrosion protection.

In some cases, to help the top protective dielectric oxide layer stay on the component and reduce cracking and delamination, the CTE mismatch between the based and the protective dielectric oxide layer is reduced by using SSAM to deposit a MMC layer (e.g., Al plus Al₂O₃, SiC, carbon nanotubes) in between the aluminum metal component (having a CTE of 24×10⁻⁶/° C.) and the dielectric oxide layer (e.g., CTE of 7×10⁻⁶/° C.). The MMC layer has a CTE between 7×10⁻⁶/° C. and 24×10⁻⁶/° C.

In one general aspect, a component for a semiconductor-processing chamber include a base including a metallic material, a MMC layer at least partly covering the base, and a dielectric layer of a non-metallic material directly on the MMC layer. The MMC layer comprises a metallic material as a continuous phase and a non-metallic material as a disperse phase, the MMC layer being formed on the base using SSAM.

Another general aspect is for a semiconductor-processing chamber component comprising a base, a metal layer, and an anodized layer. The base is made of an MMC using SSAM, and the MMC comprises a metallic material as a continuous phase and a non-metallic material as a disperse phase. The metal layer includes a metal or a metal alloy and at least partly covers the base. The metal layer is formed on the base using SSAM. The anodized layer is of a dielectric material and is on the metal layer.

Another general aspect includes a method for manufacturing a component of a semiconductor manufacturing system. The method includes an operation for providing a base including a metallic material. The method further includes an operation for depositing an MMC layer on the base, the MMC layer comprising a metallic material as a continuous phase and a non-metallic material as a disperse phase, the MMC layer deposited on the base using solid-state additive manufacturing (SSAM). Further, the method includes adding a dielectric layer of a non-metallic material on the MMC layer.

### BRIEF DESCRIPTION OF THE DRAWINGS

Various of the appended drawings merely illustrate example embodiments of the present disclosure and cannot be considered as limiting its scope.

FIG. 1 illustrates the process for adding a layer of solid material using SSAM, according to some example embodiments.

FIG. 2 illustrates an ESC for supporting a substrate within a chamber of a semiconductor manufacturing apparatus, according to same example embodiments.

FIG. 3A shows an ESC made with multiple layers of material, according to some example embodiments.

FIG. 3B shows parts build with different types of layers, according to some example embodiments.

FIG. 4 is a flowchart of a method for making a part using, at least, SSAM, according to some example embodiments.

FIG. 5 illustrates the making of a part using a metal-matrix composite and SSAM, according to some example embodiments.

FIG. 6 shows the creation of multiple layers through SSAM, according to some example embodiments.

FIG. 7 shows the creation of a part with embedded channels for heating and cooling, according to some example embodiments.

FIG. 8 shows a part with embedded channels and three layers of different characteristics, according to some example embodiments.

FIG. 9 is a flowchart of a method for making a component of a semiconductor manufacturing system, according to some example embodiments.

FIG. 10 is an etching chamber, according to some example embodiments.

FIG. 11 is a block diagram illustrating an example of a machine 900 upon or by which one or more example process embodiments described herein may be implemented or controlled.

### DETAILED DESCRIPTION

Example methods, systems, and computer programs are directed to semiconductor-processing parts made using solid-state additive manufacturing. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

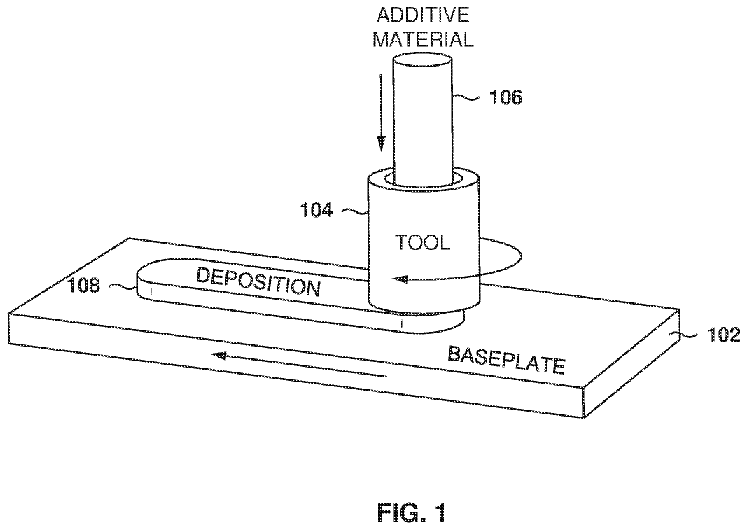

FIG. 1 illustrates the process for adding a layer of material using SSAM, according to some example embodiments. Additive manufacturing (AM), also known as three-dimensional (3D) printing, uses computer-aided design to build objects layer by layer. This contrasts with traditional manufacturing, which cuts, drills, and grinds away unwanted excess from a solid piece of material, often metal. AM is the opposite of subtractive manufacturing methodologies that take away material from existing objects to create new objects. Synonyms for AM include additive fabrication, additive processes, additive techniques, additive layer manufacturing, layer-wise manufacturing, 3D printing, and freeform fabrication.

One type of SSAM is Friction Stir Additive Manufacturing (FSAM), which refers to a metallurgical joining process in which metallic bodies are joined together, forming multi-layer structures as a result of solid-state plastic deformation and diffusion bonding.

A related technology is Friction stir welding (FSW), which is a solid-state joining process that uses a non-consumable tool to join two facing workpieces without melting the workpiece material. Heat is generated by friction between a rotating tool 104 and a workpiece material (e.g., baseplate 102), which leads to a softened region near the FSW tool 104. While the tool is traversed along the joint line, the tool mechanically intermixes the two pieces of metal, and forges the hot and softened metal by mechanical pressure, which is applied by the tool, much like joining clay or dough. FSW is often used on wrought or extruded aluminum and particularly for structures that need very low joining defects.

FSAM is used for adding layers, repairing, coating, and joining metals and metal matrix composites. A solid-state process means the material does not reach the melting temperature during the process. Further, FSAM is basically an open-atmosphere process, rarely requiring environmental control such as special vacuums or gas shield, thereby making FSAM scalable and able to make larger parts, unlike other SSAM processes. No melting means better mechanical and performance properties.

Although some embodiments are presented with reference to FSAM, any type of SSAM may be used for building parts, as described herein. FSAM is a type of severe plastic deformation (SPD), or just plastic deformation. Embodiments are presented herein with reference to FSAM solid-state additive manufacturing, but other types of solid-state AM or SPD processes may also be used for creating structures.

FSAM adds material to a base piece, referred to as baseplate 102, and is similar to FSW because there is no material melting. However, FSAM deposits a layer of material on the baseplate to add an additional deposition layer 108.

As illustrated in FIG. 1, a FSAM tool 104 spins while delivering additive material 106 to be deposited on the baseplate 102, creating a FSAM deposition layer 108. The FSAM tool 104 moves over the baseplate 102 to deposit additive material 106 throughout the baseplate 102.

With FSAM, the additive material 106 plasticizes (i.e., becomes “gummy” similar to chewing gum) as it is delivered by the head of the FSAM tool 104 at the appropriate strain rate, or rotation rate, pressure, and temperature. However, it should be noted that the additive material 106 does not reach the melting point.

As the FSAM tool 104 moves over the baseplate 102, the FSAM tool 104 applies pressure over the baseplate 102. The FSAM deposition layer 108 may have a thickness between 500 μm and 2 mm, although other values may also be possible. The FSAM deposition layer 108 does not have to be uniform over the baseplate 102, thereby allowing the possibility of creating patterns (e.g., spaces) on the layer created above the baseplate 102.

The additive material 106 may be of many different types, such as different types of aluminum and alloys, because the materials are not melted. Since the additive material 106 is not melted during the process, there is no residual stress that would otherwise occur with welding.

One SSAM process involves rotating one of the two bodies (the work piece), bringing it in contact with high pressure onto the other body (the base piece), and creating friction and heat to initiate the plastic flow of material. At the same time, the work piece is then traversed over the base piece, intermixing the materials from both the work piece and the top surface of the base piece. Each traversing pass adds the materials from the work piece onto the build materials on the base piece forming a dense layer, one layer at a time. Layer-by-layer, dense bulk materials can be formed, all in solid-state with no melting.

SSAM can build metal, metal alloy, or metal matrix composites containing additional phases such as oxides, nitrides, carbides, carbon allotropes/polymorphs, and so forth. The baseplate 102 can be a metal, metal alloy, or metal matrix composite containing additional phases such as oxides, nitrides, carbides, carbon allotropes/polymorphs, and so forth. This technology is novel as it allows dissimilar materials, including metal matrix composites, to be joined and/or consolidated without melting, forming dense layers with possible internal features/channels as the process produces structure layer-by-layer. Metal matrix consolidation otherwise formed by conventional high heat processes can result in high porosity, loss of low melting point materials, distortion from thermal environment, layer cracking from coefficient of thermal expansion mismatch between materials, and cracking.

SSAM has multiple uses for creating semiconductor manufacturing equipment parts:
1. Cladding special materials on regular materials (e.g., showerheads and pedestals).
2. Embedding features inside parts, (e.g., top-plate heaters and/or coolers, gas delivery systems).
3. Making Functionally Graded Materials (FGM) with different properties in different sections of the part (e.g., baseplate with low CTE). FGM may be characterized by the variation in composition and structure gradually over volume, resulting in corresponding changes in the properties of the material. The materials can be designed for specific function and applications. A FGM MMC is a two, or more, component composite characterized by a compositional gradient from one component to another, in contrast with traditional composites that are homogeneous mixtures.
4. Providing Fine Grained (FG) or Ultrafine Grained (UFG) materials. The UFGs have two advantages. One advantage is the ability to produce materials with a tailored grain size. The UFG materials, under specific thermal or thermo-mechanical treatment, can increase to a tailored grain size very suitable to semiconductor process. A second advantage is the ability to make feed stock for a forming or super-forming process for formable, or even non-formable, metals and alloys; the FG/UFG materials are essentially superplastic under specific strain, strain rate, and temperature. For example, the FSAM processed materials can be used for forming process for liners, cartridge cups, and so forth.

The advantages of using SSAM include:
1. 100% contact of heater/cooler with plates, which means higher efficiency.
2. Cover materials that may be sensitive to the process (e.g., exposure to plasma) with materials that are not sensitive, or are much less sensitive, to the process.
3. Control metallurgical functionality layer-by-layer (e.g., creating parts with embedded channels).

Using SSAM, it is possible to make heater, cooler, gas-dispenser, or multi-task parts that often cannot be made using conventional manufacturing methods or might be too expensive to make. With solid-state additive manufacturing, it is possible to create features inside solid materials as layers are added one at a time. These features include, but are not limited to, heater elements, cooling tubes, and tube or tubeless gas channels.

Additionally, it is possible to use several types of metals, alloys (similar or dissimilar), or composites in each of the layers to create FGM that offer different properties (e.g., heat, conductivity, reaction to plasma) on the different surfaces of the parts.

Building example parts with embedded features using SSAM provides the following benefits:
Greater flexibility in using Aluminum AA6061 and AA3003 in instances where traditionally only A356 can be used;
Greater precision for placement of internal structures within parts;
Enhanced ability to insert several types of similar or dissimilar features in one part;
Substantial elimination of elemental contamination caused by braze foils and high silicon cast alloys;
Reduction of costs because of shorter processing times and minimum usage of materials;
Reduction of costs by incorporating SSAM equipment into existing metal-machining operations, thereby enabling vertical process integration at equipment suppliers;
An ability to adopt computer numerical control (CNC) techniques for solid-state additive processing without having to invest in casting molds. Also, in some examples, no tooling for brazing is required with little or no cost associated with bulk heating furnaces;
Reduced or eliminated lead time for casting molds and tooling associated with brazing development in CNC processes;
In some CNC processes, operational tach-time is much shorter than casting and brazing. Further, SSAM is closer to being able to provide machining tolerances than casting or brazing techniques.

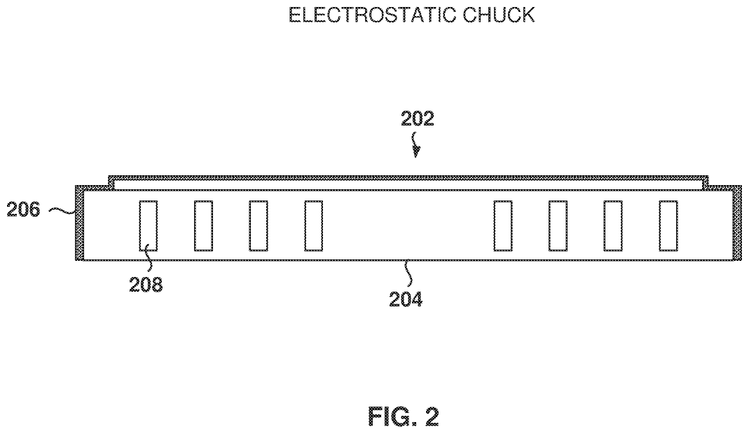

FIG. 2 illustrates an ESC 202 for supporting a substrate within a chamber of a semiconductor manufacturing apparatus, according to same example embodiments. The ESC 202 is a device for generating an attracting force between an electrode and an object at a voltage applied to the electrode. In a semiconductor manufacturing apparatus, the ESC 202 is used to hold the substrate during processing. The ESC 202 uses a baseplate with integral electrodes which are biased with high voltage to establish an electrostatic holding force between the baseplate and the substrate, thereby “chucking” the substrate.

In some example embodiments, the ESC 202 includes a baseplate 204 with a coating layer 206 and embedded distribution channels 208 for distributing gas (e.g., helium) to cool the substrate from underneath by bringing the gas to the bottom of the substrate. Some requirements for the ESC 202 are that it includes the internal distribution channels 208 for cooling fluid, provides high thermal conductivity for fast temperature switching, and be corrosion resistant (e.g., ability to be anodized or protected by other means).

In some implementations, the baseplate 204 is made of aluminum (with anodization) and the coating layer 206 is an aluminum oxide. In some implementations, the coating layer 206 is sprayed on top of the baseplate 204. In some examples, the baseplate 204 includes two or more blocks of aluminum that are then braced together to form the baseplate 204 with the embedded distribution channels 208.

The coating layer 206 can crack and delaminate during usage when the ESC 202 undergoes thermal shock in cryogenic applications, e.g., quick temperature transitions from −75° C. to 65° C. The delamination is caused by a high CTE mismatch between the aluminum metal and the aluminum oxide coating.

The coating layer 206 and the baseplate 204 together go through thermal expansion and contraction every time the ESC 202 is heated or cooled down. The aluminum component can expand substantially, because its coefficient of expansion is 24, while a coating layer 206 such as alumina Al₂O₃ has a CTE of just 8×10⁻⁶′/° C. Therefore, there is a high mismatch between the two. During the coldest operating temperature, the alumina will not contract as much as the aluminum, causing delamination over time. The opposite happens when the ESC 202 is heated; the aluminum expands much more than the alumina, which will result in peeling of the coating layer 206.

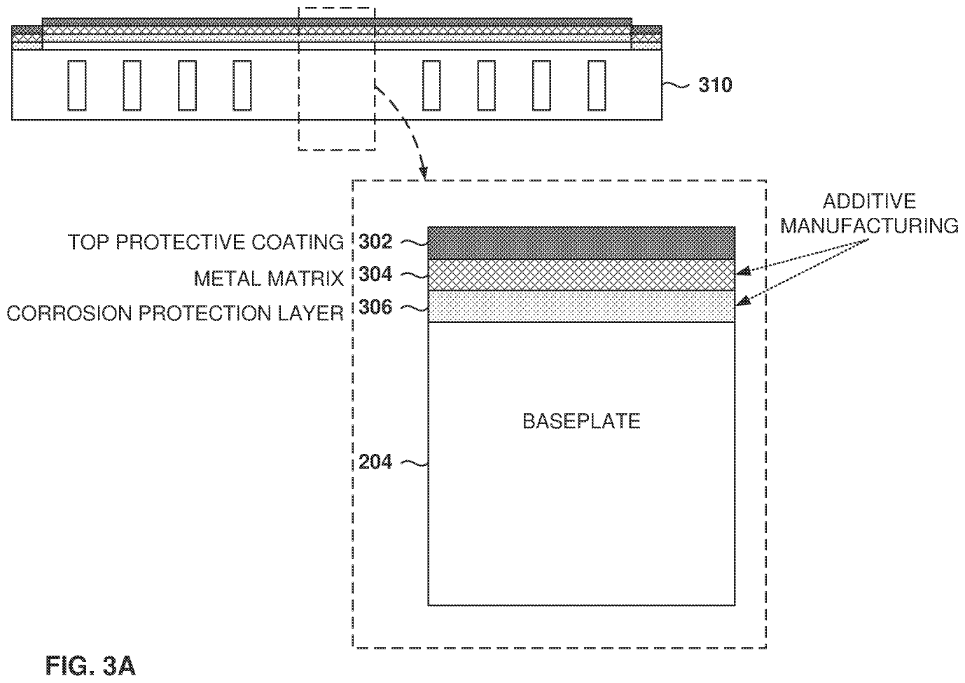

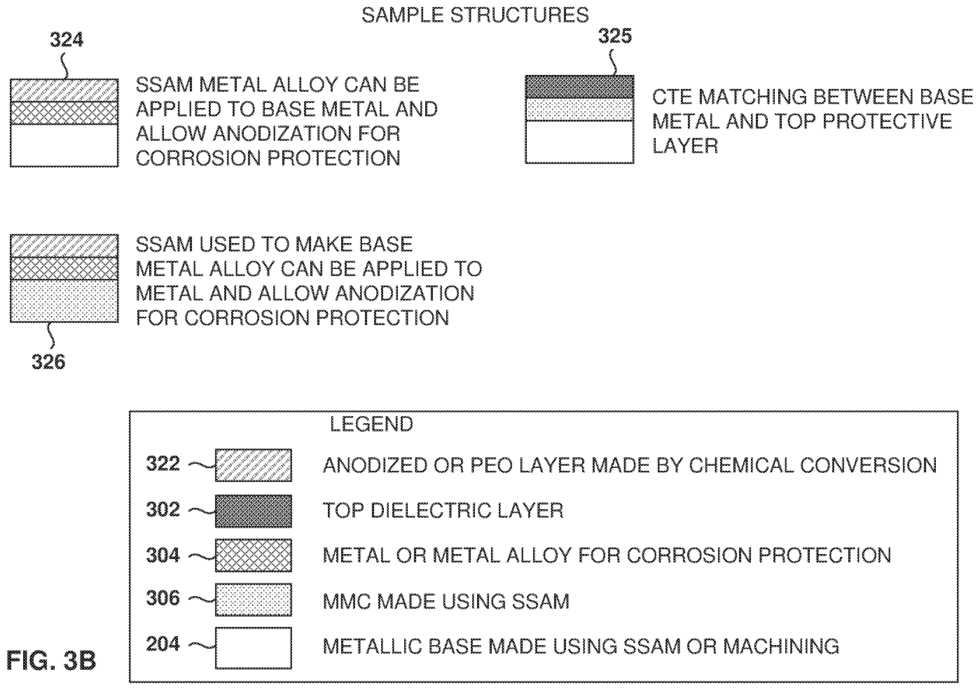

FIG. 3A shows an ESC 310 made with multiple layers of material, according to some example embodiments. In some example embodiments, the ESC 310 is made using, at least in part. SSAM to include multiple layers of protection above the baseplate 204.

The intermediate layers may have materials selected with different CTEs, gradually increasing or decreasing the value of the CTE from top to bottom, in order to avoid big mismatches in CTE between the layers. This way, the problems of delamination and peeling can be greatly reduced or completely eliminated. For example, a layer made of a combination of aluminum and alumina may be interposed between the layers of aluminum and alumina to reduce the CTE mismatch between layers, because the material made of aluminum and alumina will have a CTE that is between the CTEs of those materials.

One advantage of AM is that it allows combining layers in the solid-state. For example, a layer of alumina could be added via SSAM directly on top of aluminum. Aluminum melts at 660° C. and alumina at about 2060° C., but by using SSAM, they can be put together without melting the baseplate 204 and without the loss of material. Similarly, different aluminum composites may be added via SSAM.

In some example embodiments, the ESC 310 includes three layers above the baseplate: a first layer 306 for corrosion protection, a second layer 304 made of a metal matrix, and a third layer 302 that provides a top protective coating.

The first layer 306 is added using SSAM. Then, the second layer 304 is added using SSAM, and the third layer 302 is added using an air plasma spray process. In some example embodiments, the baseplate 204 is made by machining a block of aluminum. In other embodiments, the baseplate 204 is also made with SSAM by building up the baseplate 204 through different passes of additive manufacturing to add the aluminum with embedded features inside.

After hours of operation of the chamber, corrosive wet chemistries and gasses may penetrate the top protective coating and attack the underlying chamber component baseplate 204. The first layer 306 provides corrosion protection against the wet chemistry and aggressive gasses within the chamber processes. In some example embodiments, the first layer 306 is composed of aluminum-magnesium, or aluminum plus magnesium alloy. In some example embodiments, the first layer 306 includes 0.5% to 1.5% weight of magnesium, but other values are also possible.

For example, an aluminum-magnesium layer can be applied by SSAM onto the aluminum baseplate 204. When exposed to the chamber process, fluorine gas may penetrate the top third layer 302 with ceramic coating and react with the aluminum-magnesium to form passivating magnesium fluoride phases that prevent further attack of the underlying pure aluminum baseplate 204.

In some example embodiments, the second layer 304 has an intermediate coefficient of thermal expansion between the one from the baseplate 204 and the third layer 302 and improves adhesion of the third layer 302 during manufacturing.

In some example embodiments, the second layer 304 is a metal matrix composite that is selected to manage the CTE mismatch between the baseplate 204 and the third layer 302. By inserting layers that contain intermediate CTE values in between the metal baseplate 204 and the top protective coating of the third layer 302, the process enables the third layer 302 to adhere to the metal component of second layer 304 while they undergo expansion and contraction in changing thermal environments during operation of the chamber.

In some example embodiments, the second layer 304 includes a 0 to 40 volume percent of disperse phase (Al₂O₃, SiC, etc.) and is mixed with a combination of Al+Al₂O₃, resulting in a CTE in the range from 18×10⁻⁶/° C. to 25×10⁻⁶/° C., but other mixtures may result in a lower CTE. In other example embodiments, the range for the disperse phase is from 0 to 75 percent by volume.

The second layer 304 includes a mixture of elements from metallic substrate materials that are added using SSAM. For example, to manage the CTE mismatch between top (CTE of 26×10⁻⁶/° C.) and bottom (CTE of 7×10⁻⁶/° C.), the second layer is added is composed of, for example, a combination of aluminum and aluminum oxide, a combination of aluminum and silicon carbide, or a combination of aluminum and carbon allomorphs (e.g., nanotubes, graphene, etc.), is used. The aluminum oxide or silicon carbide in a form of powder can be incorporated into the aluminum matrix as the work piece and used to apply the second layer 304. Further, the material for the second layer 304 may be aluminum alloys, magnesium, magnesium alloys, steel, or stainless steel.

In some example embodiments, the SSAM may add a combination of two materials, and for adding the second layer 304, the aluminum is combined with the aluminum oxide or the silicon carbide powders to create the metal matrix composite. The metal matrix composite will have a CTE value between that of the aluminum and the aluminum oxide or the silicon carbide. In other example embodiments, the metal matrix composite is created previously and the layer of metal matrix composite is then added using SSAM.

In some example embodiments, the third layer 302 is then added by air plasma spray on top of the second layer 304. In other example embodiments, the third layer 302 is added using SSAM. The protective layer materials of the third layer may be oxides, rare earth oxides, fluorides, and oxyfluorides that may contain rare earth materials such as yttria, zirconia, and lanthanum oxides, rare earth oxides, fluorides, oxyfluorides containing yttrium, lanthanum, and zirconium.

It is noted that cohesion between metal and metal is better than cohesion between metal and ceramics. Similarly, cohesion between ceramics and ceramics is better than cohesion between metal and ceramics. By adding the intermediate layers, the cohesion between the layers improves because the cohesion of a mix of metal and ceramics on metal is better than the cohesion of ceramics directly on top of metal. Therefore, by adding the intermediate layers, cohesion improves as compared to the cohesion of adding the top protective coating directly on top of the metal baseplate 204.

In some example embodiments, the height of the baseplate 204 is in the range from 1 cm to 5 cm, although other values are also possible. Further, the thickness of each of the first, second, and third layers 306, 304, 302 is in the range from 250 micrometers to three millimeters, although other values are also possible.

FIG. 3B shows parts build with different types of layers, according to some example embodiments. Depending on the desired properties, parts can be made using different layers in different layouts. FIG. 3B shows the layers used to build additional example parts 324-326.

The legend shows the different types of layers, such as baseplate 204, first layer 306 for corrosion protection, the second layer 304 made of a metal matrix using SSAM, the third layer 302 that provides a top protective coating, and a fourth layer 322 that is anodized or polyethylene oxide (PEO) made by chemical conversion.

Part 324 includes a metallic base that can be made using SSAM or machined. The SSAM metal alloy can be applied to any base metal component and allows use of anodization for corrosion protection.

Part 326 includes an MMC base made using SSAM, with a metal alloy (e.g. AlMg) for corrosion protection, and a top anodized layer for protection in the chamber during manufacturing. SSAM can be used to make the base and to add the metal alloy, allowing for the anodization process; otherwise, direct anodization of the MMC base would result in a non-uniform anodized layer.

Part 325 includes a metal based plus a MMC layer for CTE mismatching with the top protective dielectric oxide layer. The benefit is the CTE matching between the base metal and the top protective layer, with better top layer adhesion and a longer component lifetime.

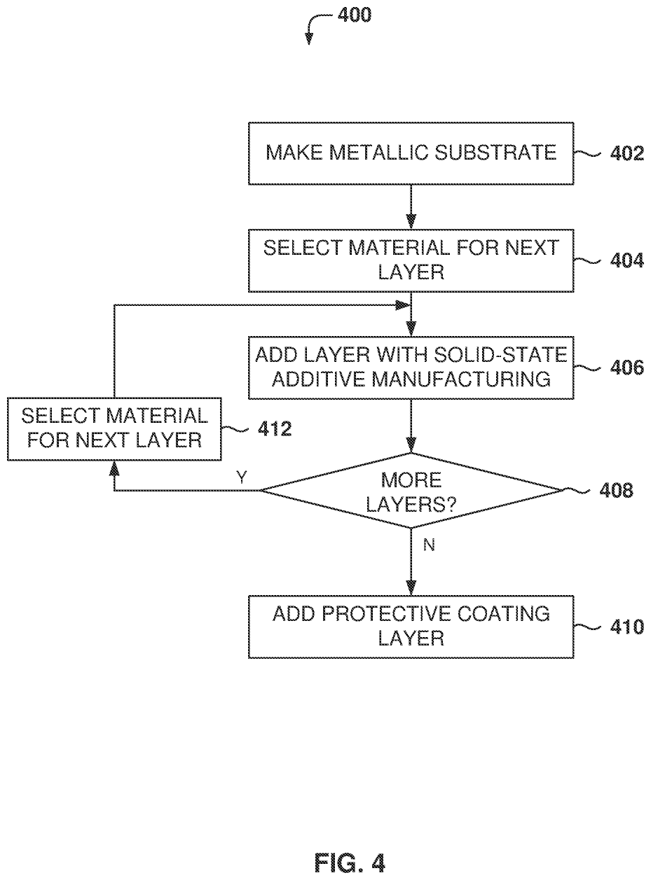

FIG. 4 is a flowchart 400 of a method for making a part using, at least, SSAM, according to some example embodiments. At operation 402, a metallic substrate is made, such as the baseplate 204 in FIG. 3A. The metallic substrate may be machined or may be build using SSAM.

At operation 404, the material is selected for a layer to be added to the substrate. In some example embodiments, the material is aluminum with magnesium elements or stainless steel, aluminum oxide, yttria oxide, zirconium oxide, or another type of oxide. Additionally, properties of different ceramics may be considered to select the ceramic for mixing with the metal, such as to get better corrosion resistance. For example, if aluminum is combined with alumina, heat conductivity is improved.

In some example embodiments, the material is selected as a material with intermediate composition between the layers, meaning that the material may be selected to gradually change the characteristics of the layers for a gradual transition between the baseplate and the top layer, such as by choosing components with gradual variations in the CTE to provide a gradual transition in CTE between the baseplate and the top layer.

In some example embodiments, a metal (e.g., aluminum) is combined with other filler components in different ratios. In some example embodiments, the added material to the metal is added in a range from 50% mass percentage to 80% mass percentage, although other values are also possible.

At operation 406, a layer of the selected material is added with SSAM. Further, at operation 408, a check is made to determine if additional layers will be added using SSAM. The material may be, for example, aluminum with aluminum oxide; aluminum with silicon carbide; aluminum with yttrium oxide; aluminum with carbon nanotube (CNT), graphine, or buckyballs; or other carbon allotropes.

If additional layers will be added, the method flows to operation 412 to select the material for the next layer, and if additional layers are not added with SSAM, the method flows to operation 410.

At operation 410, a top protective coating layer is added, such as third layer 302 of FIG. 3A. The top layer may be adding using an air spray or other techniques. It is noted that, in some example embodiments, operation 410 is optional as the top layer is also added using SSAM. Further, in other embodiments, more than one layer may be added, on top or in between layers, using other techniques rather than SSAM.

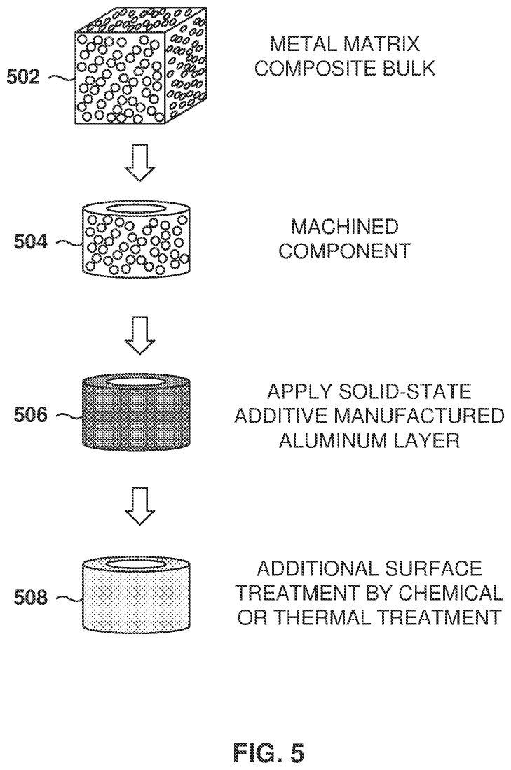

FIG. 5 illustrates the making of a part using a metal-matrix composite and SSAM, according to some example embodiments. Initially, a metal matrix composite bulk 502 is manufactured. A metal matrix composite is a composite material with at least two constituent parts, one being a metal and the other material being a different metal or another material, such as a ceramic or an organic compound. In some example embodiments, the materials that may be added to the metal are oxides, nitrides, carbides, carbon allotropes, polymorphs, and so forth.

Afterwards, the metal matrix composite bulk 502 is machined to create a machined component 504. In some example embodiments, the machined component 504 is a cylindrical piece used for making a part for the semiconductor manufacturing chamber, such as the ESC or the showerhead.

Further, a layer of aluminum is added using SSAM to obtain piece 506. In some example embodiments, a robotic arm is used to apply the layer of aluminum on top of the machined component 504, because the layer is applied three dimensionally instead of on top of a flat surface. For example, a SSMA device includes a five-axes robotic arm configured to move with three axes on top of the surface being covered.

Further, additional layers may be added to piece 506 by surface treatment, such as chemical or thermal treatments. The result is part 508 with the embedded metal layer and the top protective coating.

In some cases, a layer of aluminum plus silicon carbide is being added to the base material. Anodization is used to provide corrosion protection. The aluminum would get anodized, converting to a surface layer of aluminum oxide. However, the silicon carbide that is embedded cannot do the same. This means that corrosion protection would not be continuous throughout the part and corrosion may appear in the chamber.

To avoid this problem, the aluminum layer is added on top of the machined component 504 made of the metal matrix composite. The aluminum then provides a continuous layer for corrosion protection.

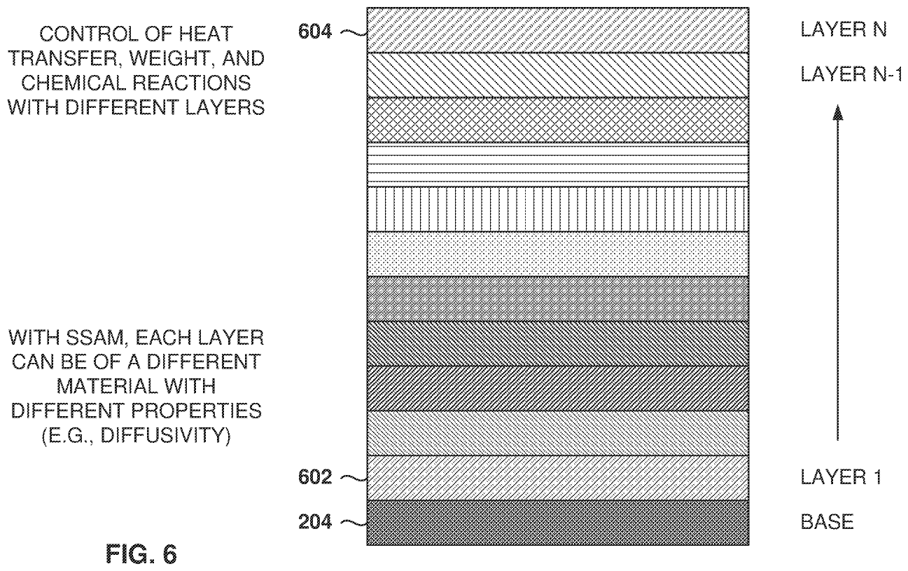

FIG. 6 shows the creation of multiple layers through SSAM, according to some example embodiments. SSAM allows parts composed of multiple layers. The selection of layers is designed to control the properties of the part, such as strength, heat transfer, weight, and chemical reactions of the different layers.

With SSAM, layers are added one at a time, starting with the baseplate 204 and then adding additional layers 602 to 604 through SSAM. Each of the layers may have a different material with different properties (e.g., electrical or heat conductivity and diffusivity).

For example, if the top layer is designed to be in contact with the plasma chamber or in contact with chemicals, the top layer may be formed of a high-performance material that behaves well when exposed to a plasma chamber or the chemicals. However, other materials may be formed with less expensive materials if the materials will not be in contact with the plasma chamber. Further, not all the layers have to be made of different materials; the same material may be used on several layers.

For example, several bottom layers may be formed with aluminum 6061 that is strong and cheaper than aluminum low zinc 3003. The top two layers may be formed with aluminum low zinc 3003 that has less impurities, so the impurities will not contaminate the chamber during operation.

Many types of materials may be used as the baseplate 204 and for cladding with a SSAM process. Some of the base materials include rolled aluminum 6061, cast aluminum 356, cast aluminum 357, and stainless steel 316L or 304.

For example, if a carbon allotrope is included in the metal matrix composite for one of the layers, the inclusion of the carbon allotrope will improve the thermal conductivity of the part, better than the thermal conductivity of pure aluminum. This will help to quickly conduct heat into and away from the ESC to assist in applications with fast thermal switching during processing of the substrate.

In general, the thermal conductivity is calculated based on the volume percentage of the mix. For example, in a mix with equal parts by volume, the thermal conductivity will be the average of the thermal conductivity of the two materials mixed. Based on this property, the different layers may be designed for gradual changes in the CTE from the bottom to the top by changing the percentages of the elements being mixed. For example, going from a CTE of 24×10⁻⁶/° C. for pure aluminum to a CTE of 8×10⁻⁶/° C. for alumina, three layers maybe included between the aluminum and the alumina, with CTEs of 12×10⁻⁶/° C., 16×10⁻⁶/° C., and 20×10⁻⁶/° C. To obtain a CTE of 12×10⁻⁶/° C., volume percentages of 75% aluminum and 25% alumina are mixed, such that the CTE of the combination is equal to 24×10⁻⁶/° C.×0.75+8×10⁻⁶/° C.×.0.25, or 12×10⁻⁶/° C. For a CTE of 16×10⁻⁶/° C., an equal mix by volume is used, and for a CTE of 20×10⁻⁶/° C., 75% aluminum with 25% alumina is used.

The number of layers may be selected to control how different the CTE is from layer to layer. The number of layers may then be determined, and in some example embodiments, the number of layers is in the range between one and 20, although other values are also possible.

Some example materials for SSAM include aluminum alloy, aluminum low zinc 3003, aluminum 1050, nickel, nickel-chromium alloy (e.g., by weight, 20-55% nickel, 17%-21% chromium, ˜5% niobium, ˜3% molybdenum, ˜1% titanium, iron balance), nickel-chromium-molybdenum alloy (e.g., by weight, 56% nickel, 22% chromium, 13% molybdenum, 3% iron, 2% cobalt, 3% tungsten, 0.5% manganese), tantalum, cadmium, and pure aluminum.

With SSAM, new possibilities are open to create new parts coated with materials that would have been too expensive to use in the past, such as platinum or an aluminum alloy having at least 99 mass percentage content of aluminum and a small content of magnesium. Further, some of these materials are not machinable and cannot be cast so the use of SSAM enables the use of these materials.

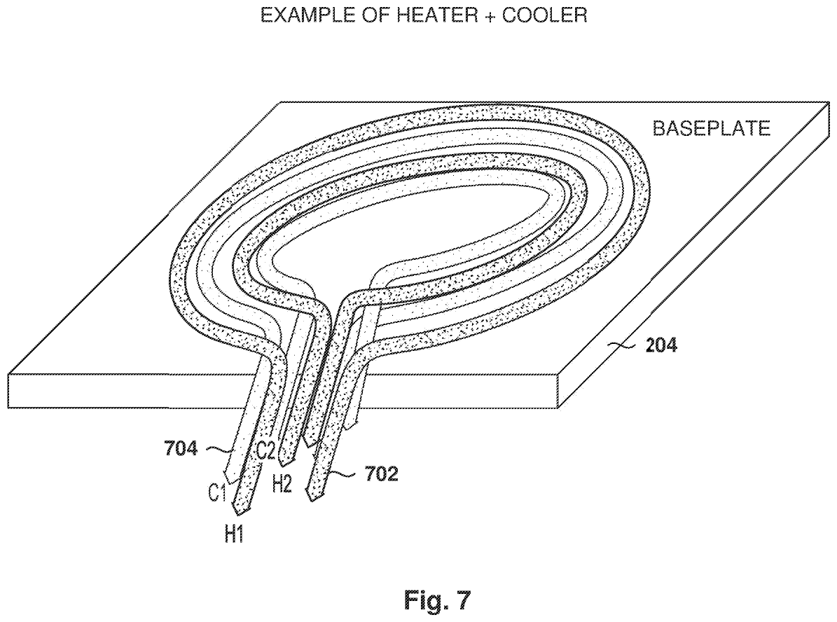

FIG. 7 shows the creation of a part with embedded channels for heating and cooling, according to some example embodiments. In some cases the channels may be included for air cooling, and in other cases, channels that carry liquids or gases may be embedded within the ESC.

FIG. 7 shows a perspective view of the baseplate 204 with embedded heating elements 702 and cooling elements 704. The embedded heating elements 702 and cooling elements 704 circle around above the baseplate 204, where a fluid may enter on one end and exit out the other end. Although the heating elements 702 and cooling elements 704 illustrated are disposed on a horizontal plane, other embodiments may include channels disposed for vertical transport, or some may be a combination of horizontal and vertical travel.

After adding the embedded channels, SSAM is applied to cover the embedded channels. Further, the process may be repeated to add additional embedded channels and different layers.

In some example embodiments, machining is performed on the baseplate 204 to generate grooves to hold the embedded features. Further, the features (heating elements 702 and cooling elements 704) are placed (e.g., embedded) on the machined part. Further, SSAM manufacturing is performed over the part to cover the embedded features, resulting in a part with embedded channels.

The process may be repeated several times to obtain several layers of embedded features. Further, the embedded features do not have to be the same in each of the layers. For example, one layer may be used for cooling elements and another layer may be used for heating elements, or the order of features in each layer may be changed, such as by alternating elements.

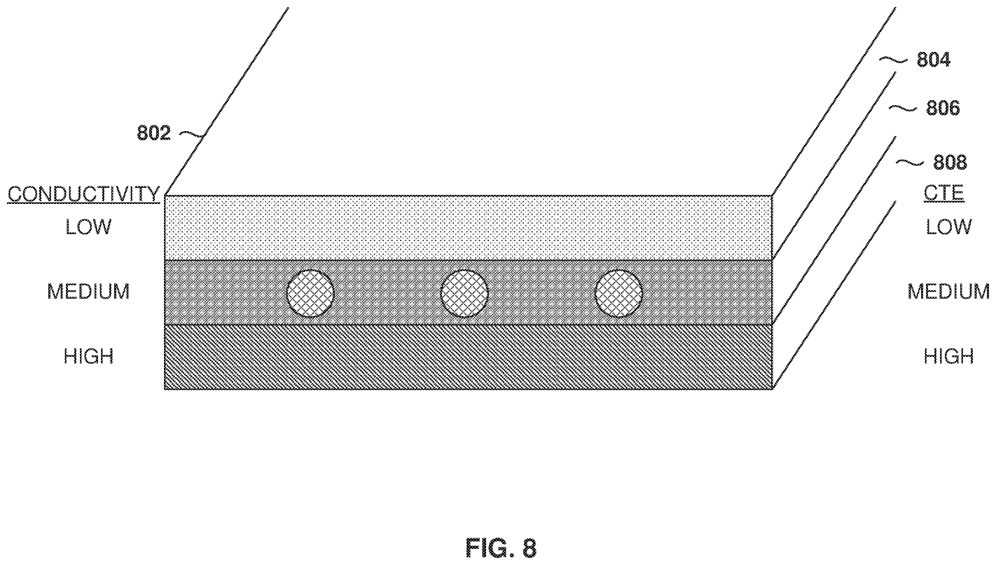

FIG. 8 shows an example ESC with embedded channels and three layers of different characteristics, according to some example embodiments. ESCs have electrical heaters inside to heat the substrate, and vapor from the chamber may become in contact with the ESCs. As discussed above, some ESCs are made of aluminum 3003, which is an aluminum alloy with a diluted amount of manganese and silicon. However, aluminum 3003 cannot support a very high operating temperature.

Another problem with aluminum 3003 ESCs is expedited fluorination that may cause the ESC to start flaking. Flaking may be due to fluorination, where a radical of fluorine reacts with the aluminum or the aluminum alloys.

When the ESC flakes, the ESC can create powder material (aluminum fluoride) that becomes vapor, and the particles in the vapor will contaminate the manufacturing chamber.

To avoid the problems of aluminum 3003, ESCs may be made of other materials, such as aluminum alloys. However, machinability is very low for the aluminum alloys and the aluminum allows are also expensive (e.g., 5 to 7 times the cost of aluminum 3003).

One solution for creating a durable ESC is to start with a stronger, cheaper material, such as aluminum 6061, and then clad one layer of material that is better for chemical contact in the chamber, such as pure aluminum or aluminum alloys. This way, the ESC has chemical resistance and strong structural integrity. Further, the layers do not have to have the same size, and a small layer of pure aluminum or aluminum alloy might be built on top of a thicker aluminum 6061 baseplate.

The layers may be of different materials. In some example embodiments, the head supplies two different materials simultaneously, such as aluminum and aluminum fluoride. The head includes two feeders, one for powder A and one for powder B. The materials may then be combined, for example a ceramic and a metal to process at the same time. In some example embodiments, a binder may also be added to the process, such as to bind aluminum fluoride. This way, different alloys or composite compounds may be created during the layer wise cladding process that may not easily be available commercially.

One ESC 802 is constructed with a baseplate 808 with high CTE (e.g., 24×10⁻⁶/° C.), adding an intermediate layer 806 with a medium CTE (e.g., 16×10⁻⁶/° C.) and a top layer 804 with the low CTE (e.g., 8×10⁻⁶/° C.).

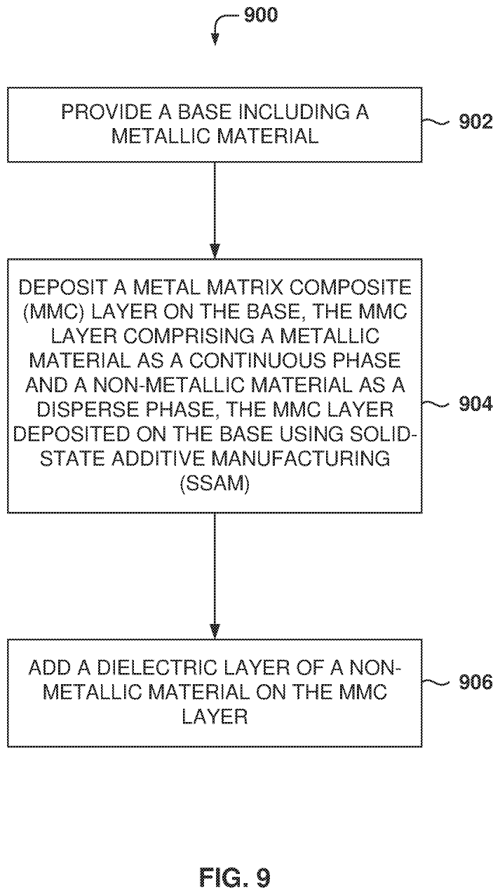

FIG. 9 is a flowchart of a method 900 for making a component of a semiconductor manufacturing system, according to some example embodiments. In some example embodiments, the component is an ESC. While the various operations in this flowchart are presented and described sequentially, one of ordinary skill will appreciate that some or all of the operations may be executed in a different order, be combined or omitted, or be executed in parallel.

At operation 902, a base is provided, the base including a metallic material.

From operation 902, the method 900 flows to operation 904 for depositing an MMC layer on the base. The MMC layer comprises a metallic material as a continuous phase and a non-metallic material as a disperse phase, and the MMC layer is deposited on the base using SSAM.

From operation 904, the method 900 flows to operation 906 where a dielectric layer of a non-metallic material is added on the MMC layer.

In one example, the method 900 further includes, before adding the MMC layer, adding a corrosion-protection layer, including aluminum and magnesium, on the base, the corrosion-protection layer formed using SSAM.

In one example, the MMC layer is one of a combination of aluminum and aluminum oxide, a combination of aluminum and silicon carbide, or a combination of aluminum and carbon allomorphs.

In one example, the dielectric layer is one or more of an oxide, a rare earth oxide, a fluoride, or an oxyfluoride that contains rare earth material, wherein the dielectric layer is added using air plasma spraying.

In one example, the thickness of the MMC layer and the dielectric layer is in a range from 250 micrometers to three millimeters.

In one example, SSAM utilizes a rotating head that applies pressure to a first material and a second material causing the first material to plasticize without reaching a melting point.

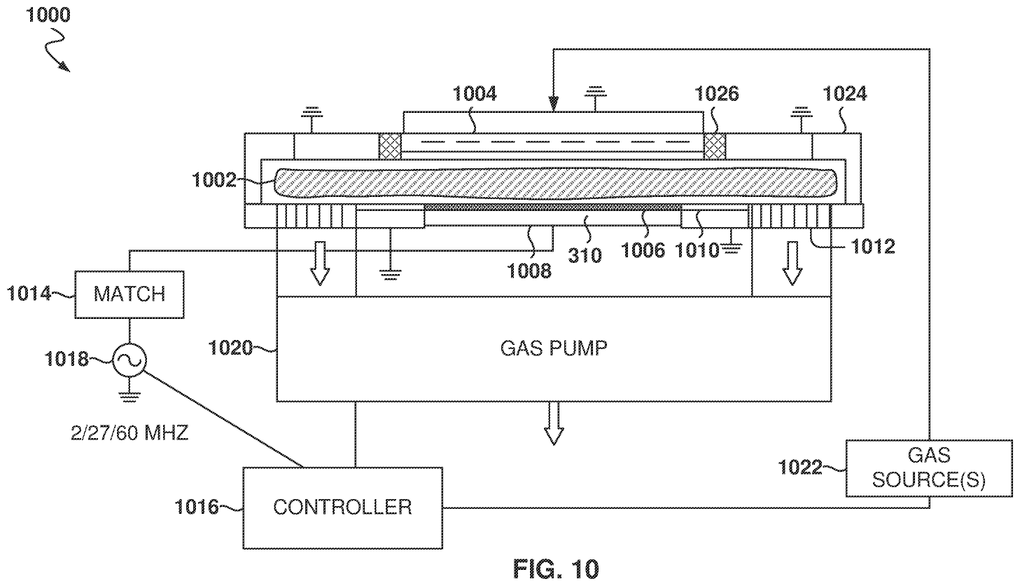

FIG. 10 shows an etching chamber 1000, according to one embodiment. Exciting an electric field between two electrodes is one of the methods to obtain radiofrequency (RF) gas discharge in an etching chamber. When an oscillating voltage is applied between the electrodes, the discharge obtained is referred to as a Capacitive Coupled Plasma (CCP) discharge.

Plasma 1002 may be created utilizing stable feedstock gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface, and producing volatile molecules, which can be pumped away. When plasma is created, the positive ions are accelerated from the plasma across a space-charge sheath separating the plasma from the chamber walls to strike the substrate surface with enough energy to remove material from the substrate surface. This is known as ion bombardment or ion sputtering. Some industrial plasmas, however, do not produce ions with enough energy to efficiently etch a surface by purely physical means.

A controller 1016 manages the operation of the chamber 1000 by controlling the different elements in the chamber, such as RF generator 1018, gas sources 1022, and gas pump 1020. In one embodiment, fluorocarbon gases, such as CF₄ and C—C₄F₈, are used in a dielectric etch process for their anisotropic and selective etching capabilities, but the principles described herein can be applied to other plasma-creating gases. The fluorocarbon gases are readily dissociated into chemically reactive by-products that include smaller molecular and atomic radicals. These chemically reactive by-products etch away the dielectric material, which in one embodiment can be SiO₂ or SIOCH for low-k devices.

The chamber 1000 illustrates a processing chamber with a top electrode 1004 and a bottom electrode 1008. The top electrode 1004 may be grounded or coupled to an RF generator (not shown), and the bottom electrode 1008 is coupled to RF generator 1018 via matching network 1014. RF generator 1018 provides RF power in one, two, or three different RF frequencies. According to the desired configuration of the chamber 1000 for a particular operation, at least one of the three RF frequencies may be turned on or off. In the embodiment shown in FIG. 10, RF generator 1018 provides 2 MHz, 27 MHz, and 60 MHz frequencies, but other frequencies are also possible.

The chamber 1000 includes a gas showerhead on the top electrode 1004 to input gas into the chamber 1000 provided by gas source(s) 1022 and a perforated confinement ring 1012 that allows the gas to be pumped out of the chamber 1000 by gas pump 1020. In some example embodiments, the gas pump 1020 is a turbomolecular pump, but other type of gas pumps may be utilized.

When substrate 1006 is present in the chamber 1000, silicon focus ring 1010 is situated next to the substrate 1006 such that there is a uniform RF field at the bottom surface of the plasma 1002 for uniform etching on the surface of the substrate 1006. The embodiment of FIG. 10 shows a triode reactor configuration where the top electrode 1004 is surrounded by a symmetric RF ground electrode 1024. Insulator 1026 is a dielectric that isolates ground electrode 1024 from top electrode 1004.

Each frequency may be selected for a specific purpose in the substrate manufacturing process. In the example of FIG. 10, with RF power provided at 2 MHz, 27 MHz, and 60 MHz, the 2 MHz RF power provides ion energy control, and the 27 MHz and 60 MHz power provide control of the plasma density and the dissociation patterns of the chemistry. This configuration, where each RF power may be turned on or off, enables certain processes that use ultra-low ion energy on the substrates or substrates and certain processes (e.g., soft etch for low-k materials) where the ion energy has to be low (under 1000 or 200 eV).

In another embodiment, a 60 MHz RF power is used on the top electrode 1004 to get ultra-low energies and very high density. This configuration allows chamber cleaning with high density plasma when the substrate is not in the chamber 1000, while minimizing sputtering on the ESC 310 surface. The ESC 310 surface is exposed when the substrate is not present, and any ion energy on the surface should be avoided, which is why the bottom 2 MHz and 27 MHz power supplies may be off during cleaning.

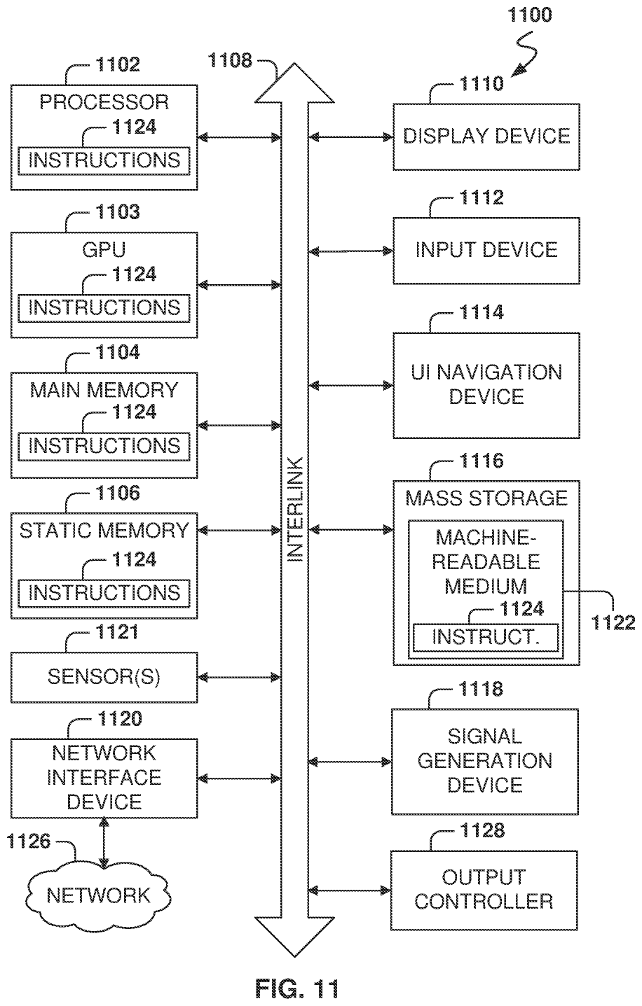

FIG. 11 is a block diagram illustrating an example of a machine 1100 upon or by which one or more example process embodiments described herein may be implemented or controlled. In alternative embodiments, the machine 1100 may operate as a standalone device or may be connected (e.g., networked) to other machines. In a networked deployment, the machine 1100 may operate in the capacity of a server machine, a client machine, or both in server-client network environments. In an example, the machine 1100 may act as a peer machine in a peer-to-peer (P2P) (or other distributed) network environment. Further, while only a single machine 1100 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, a number of components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1100 may include a hardware processor 1102 (e.g., a central processing unit (CPU), a hardware processor core, or any combination thereof), a graphics processing unit (GPU) 1103, a main memory 1104, and a static memory 1106, some or all of which may communicate with each other via an interlink (e.g., bus) 1108. The machine 1100 may further include a display device 1110, an alphanumeric input device 1112 (e.g., a keyboard), and a user interface (UI) navigation device 1114 (e.g., a mouse). In an example, the display device 1110, alphanumeric input device 1112, and UI navigation device 1114 may be a touch screen display. The machine 1100 may additionally include a mass storage device (e.g., drive unit) 1116, a signal generation device 1118 (e.g., a speaker), a network interface device 1120, and one or more sensors 1121, such as a Global Positioning System (GPS) sensor, compass, accelerometer, or another sensor. The machine 1100 may include an output controller 1128, such as a serial (e.g., universal serial bus (USB)), parallel, or other wired or wireless (e.g., infrared (IR), near field communication (NFC)) connection to communicate with or control one or more peripheral devices (e.g., a printer, card reader).

The mass storage device 1116 may include a machine-readable medium 1122 on which is stored one or more sets of data structures or instructions 1124 (e.g., software) embodying or utilized by any one or more of the techniques or functions described herein. The instructions 1124 may also reside, completely or at least partially, within the main memory 1104, within the static memory 1106, within the hardware processor 1102, or within the GPU 1103 during execution thereof by the machine 1100. In an example, one or any combination of the hardware processor 1102, the GPU 1103, the main memory 1104, the static memory 1106, or the mass storage device 1116 may constitute machine-readable media.

While the machine-readable medium 1122 is illustrated as a single medium, the term “machine-readable medium” may include a single medium, or multiple media, (e.g., a centralized or distributed database, and/or associated caches and servers) configured to store the one or more instructions 1124.

The term “machine-readable medium” may include any medium that is capable of storing, encoding, or carrying instructions 1124 for execution by the machine 1100 and that cause the machine 1100 to perform any one or more of the techniques of the present disclosure, or that is capable of storing, encoding, or carrying data structures used by or associated with such instructions 1124. Non-limiting machine-readable medium examples may include solid-state memories, and optical and magnetic media. In an example, a massed machine-readable medium comprises a machine-readable medium 1122 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1124 may further be transmitted or received over a communications network 1126 using a transmission medium via the network interface device 1120.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

1. A component for a processing chamber, the component comprising:
a base including a metallic material;
a metal matrix composite (MMC) layer at least partly covering the base, the MMC layer comprising a metallic material as a continuous phase and a non-metallic material as a disperse phase, the MMC layer formed on the base using solid-state additive manufacturing (SSAM); and
a dielectric layer of a non-metallic material directly on the MMC layer.

2. The component as recited in claim 1, further comprising:
a corrosion-protection layer, including aluminum and magnesium, at least partly covering the base, the corrosion-protection layer formed using SSAM.

3. The component as recited in claim 1, wherein the MMC layer is one of a combination of aluminum and aluminum oxide, a combination of aluminum and silicon carbide, or a combination of aluminum and carbon allomorphs.

4. The component as recited in claim 1, wherein the dielectric layer is one or more of an oxide, a rare earth oxide, a fluoride, or an oxyfluoride that contains rare earth material, wherein the dielectric layer is added using air plasma spraying.

5. The component as recited in claim 1, wherein a thickness of the MMC layer and the dielectric layer is in a range from 250 micrometers to three millimeters.

6. The component as recited in claim 1, wherein the SSAM utilizes a rotating head that applies pressure to a first material and a second material causing the first material to plasticize without reaching a melting point.

7. The component as recited in claim 1, wherein coefficient of linear thermal expansion (CTE) values for the base, the MMC layer, and the dielectric layer are in decreasing order.

8. The component as recited in claim 1, wherein a coefficient of linear thermal expansion (CTE) value of the base is in a range from 20×10⁻⁶/° C. to 28×10⁻⁶/° C. and a CTE value of the dielectric layer is in a range from 6×10⁻⁶/° C. to 10×10⁻⁶/° C.

9. A component for a processing chamber, the component comprising:
a base of a metal matrix composite (MMC) made using solid-state additive manufacturing (SSAM), the MMC comprising a metallic material as a continuous phase and a non-metallic material as a disperse phase;
a metal layer, including a metal or a metal alloy, at least partly covering the base, the metal layer formed on the base using SSAM; and
an anodized layer of a dielectric material on the metal layer.

10. The component as recited in claim 9, wherein the MMC includes aluminum and one or more of an oxide, a nitride, a carbide, a carbon allotrope, or a carbon polymorph.

11. The component as recited in claim 9, wherein the SSAM utilizes a rotating head that applies pressure to the MMC material and the metal or metal alloy of the metal layer to cause the MMC to plasticize without reaching a melting point.

12. The component as recited in claim 9, wherein adding the metal layer using SSAM includes utilizing a robotic arm to apply the metal layer three dimensionally, the robotic arm configured to move with three axes adjacent to a surface being covered.

13. The component as recited in claim 9, wherein the anodized layer is one or more of an oxide, a rare earth oxide, a fluoride, or an oxyfluoride that contains rare earth material, wherein the anodized layer is added using anodization.

14. The component as recited in claim 9, wherein a thickness of the metal layer and the anodized layer is in a range from 250 micrometers to three millimeters.

15. The component as recited in claim 9, wherein a coefficient of thermal expansion (CTE) values for the base, metal layer, and anodized layer are in decreasing order.

16. A method for manufacturing a component of a manufacturing system, the method comprising:
providing a base including a metallic material;
depositing a metal matrix composite (MMC) layer on the base, the MMC layer comprising a metallic material as a continuous phase and a non-metallic material as a disperse phase, the MMC layer deposited on the base using solid-state additive manufacturing (SSAM); and
adding a dielectric layer of a non-metallic material on the MMC layer.

17. The method as recited in claim 16, further comprising:
before adding the MMC layer, adding a corrosion-protection layer, including aluminum and magnesium, on the base, the corrosion-protection layer formed using SSAM.

18. The method as recited in claim 16, wherein the MMC layer is one of a combination of aluminum and aluminum oxide, a combination of aluminum and silicon carbide, or a combination of aluminum and carbon allomorphs.

19. The method as recited in claim 16, wherein the dielectric layer is one or more of an oxide, a rare earth oxide, a fluoride, or an oxyfluoride that contains rare earth material, wherein the dielectric layer is added using air plasma spraying.

20. The method as recited in claim 16, wherein a thickness of the MMC layer and the dielectric layer is in a range from 250 micrometers to three millimeters.
